(19) United States
(12) Patent Application Publication
(10) Pub. No.: US 2013/0187185 A1
(43) Pub. Date: Jul. 25, 2013

(54) Electronic Article and Method of Forming

(71) Applicants: David Deshazer, Bay City, MI (US); Udo Pernisz, Midland, MI (US); Ludmil Zambov, Midland, MI (US)

(72) Inventors: David Deshazer, Bay City, MI (US); Udo Pernisz, Midland, MI (US); Ludmil Zambov, Midland, MI (US)

(73) Assignee: DOW CORNING CORPORATION, Midland, MI (US)

(21) Appl. No.: 13/825,514

(22) PCT Filed: Sep. 22, 2010
(86) PCT No.: PCT/US2010/049829

§ 371 Date: Mar. 21, 2013

(51) Int. Cl. H01L 31/0232; H01L 33/58

(52) U.S. Cl. CPC H01L 31/02327; H01L 33/58
USPC 257/98; 438/29; 438/69; 257/432

(57) ABSTRACT

An electronic article includes an optoelectronic semiconductor having a refractive index of 3.7±2 and a dielectric layer disposed on the optoelectronic semiconductor. The dielectric layer has a thickness of at least 50 μm and a refractive index of 1.4±0.1. The electronic article includes a gradient refractive index coating (GRIC) that is disposed on the optoelectronic semiconductor and that has a thickness of from 50 to 400 nm. The refractive index of the GRIC varies along the thickness from 2.7±0.7 to 1.5±0.1. The GRIC also includes a gradient of a carbide and an oxycarbide along the thickness. The carbide and the oxycarbide each independently include at least one silicon or germanium atom. The article is formed by continuously depositing the GRIC using plasma-enhanced chemical vapor deposition in a dual frequency configuration and subsequently disposing the dielectric layer on the GRIC.

### FIELD OF THE INVENTION

The present invention generally relates to an electronic article and a method of forming the article. The electronic article includes an optoelectronic semiconductor, a dielectric layer, and a gradient refractive index coating (GRIC) including a gradient of a carbide and an oxycarbide.

### DESCRIPTION OF THE RELATED ART

Optoelectronic semiconductors, and electronic articles that include such semiconductors, are well known in the art. Common optoelectronic semiconductors include photovoltaic (solar) cells and diodes. Photovoltaic cells convert light of many different wavelengths into electricity. Conversely, diodes, such as light emitting diodes (LEDs), generate light of many different wavelengths from electricity.

### Photovoltaic Cells:

There are two general types of photovoltaic cells, wafers and thin films. Wafers are thin sheets of semiconductor material that are typically formed from mechanically sawing the wafer from a single crystal or multicrystal ingot. Alternatively, wafers can be formed from casting. Thin film photovoltaic cells usually include continuous layers of semi-conducting materials deposited on a substrate using sputtering or chemical vapor deposition processing techniques.

Typically, the photovoltaic cells are included in photovoltaic cell modules that also include tie layers, substrates, superstrates, and/or additional materials that provide strength and stability. In many applications, the photovoltaic cells are encapsulated to provide additional protection from environmental factors such as wind, rain, temperature, and humidity and physical factors such as stress, strain, torsion, etc.

### Light Emitting Diodes:

LEDs generally include one or more diodes that emit light when activated and typically utilize either flip chips or wire bonded chips that are connected to the diodes to provide power Like the photovoltaic cells, many LEDs also include tie layers, optical layers, substrates, superstrates, and/or additional materials to provide protection from environmental factors.

### Efficiency of Electronic Articles Including Optoelectronic Semiconductors:

The efficiency (e.g. power generation from useful light) of photovoltaic modules is related to an amount of useful light contacting the photovoltaic cells. The useful light includes electromagnetic energy at wavelengths which, when absorbed by the photovoltaic cells, results in the generation of carriers and charge. The efficiency of LEDs, on the other hand, is related to the amount of useful light produced and emitted based on a certain electrical input. In both photovoltaic cells and LEDs, transmission of useful light (whether in or out) can be limited by optical interference, reflection and absorption of the light by the optical layers, tie layers, substrates, superstrates, and addition materials described above, in addition to other factors.

Different technologies have been developed to increase conversion efficiency, reduce light reflection, and reduce light absorption of electronic articles that include optoelectronic semiconductors. These technologies include texturing surfaces of the electronic articles, adding layers of intermediate index of refraction to the electronic articles, and including antireflective coatings in the electronic articles.

Texturing surfaces reduces reflection by increasing a number of interactions with a given interface from one in flat surfaces, to two, three or more. Each interaction results in more incident light passing through the interface. Different methods have been developed for surface texturization including wet chemical etching, plasma etching, mechanical scribing, and photolithography. However, texturing thin and multicrystalline silicon is problematic due to the brittleness and high breakability of polycrystalline silicon wafers. Mechanical scribing of the surfaces often produces considerable damage such as surface tearing surrounding scribe lines. Etching the surfaces is also problematic since differing crystallographic grain orientations in polycrystalline silicon cause selective etching along specific directions making this process non-uniform. Moreover, texturing increases production costs and removes active photovoltaic material. In addition, texturing cannot be used on thin film solar cells.

Antireflective coatings have also been utilized and are designed to minimize reflection at interfaces through destructive interference of reflected light thereby improving optical properties. Antireflective coatings are typically applied on textured surfaces to reduce reflection further. Typically, antireflective coatings are designed to minimize absorption and maximize light transmission, designed to have good adhesion and durability, designed to have passivation functions, and designed to be produced at low cost. Since light entering or exiting optoelectronic semiconductors tends to be broadband, antireflective coatings usually need to be efficient over the entire solar spectrum and for all angles of light incidence. However, single layer antireflective coatings provide minimum reflection at a specific wavelength and angle and thus are only effective for small ranges of wavelengths and angles of incident light. Moreover, conventional antireflective coatings that include silicon oxide and nitride are prone to formation of defects at various interfaces because of high temperatures or plasma powers required for deposition.

High index surfaces, such as silicon surfaces, reflect about 35% of incident light of the AM1.5G solar spectrum in contact with air. Antireflective coatings can be formed using silicon carbide which has excellent mechanical properties such as hardness and wear resistance. However, these antireflective coatings are formulated using silane (SiH₄) gas which is pyrophoric and presents safety hazards. In some cases, oxygen and hydrogen are also combined with the silane gas, thereby further increasing the hazards. Moreover, these antireflective coatings typically absorb excess amounts of useable light (whether traveling in or out of the optoelectronic semiconductors). The absorption and reflection of light limits efficiency, generates excess heat which degrades the antireflective coatings, destabilizes electrical properties of the electronic articles, and reduces an overall useful working life of the electronic articles.

WO 2009/143618 discloses formation of antireflective coatings as single layers, multiple layers, and as graded films in electronic articles. These antireflective coatings are formed using processes involving numerous different energy sources such as electrical heating, irradiation, lasers, radio frequencies and plasma. More specifically, the ‘618 application teaches use of plasma-enhanced chemical vapor deposition (PECVD) to tune a ratio of silicon and nitrogen as a function of RF power, substrate temperature, and composition of gas mixtures to form a graded silicon nitride film in an electronic article. However, the PECVD methods used in the '618 application are discontinuous (i.e., interrupted) which causes formation of a series of optical interfaces in the graded films thereby reducing the applicability, optical, and electrical properties of the electronic articles. Accordingly, there remains an opportunity to develop a method of forming an improved article.

### SUMMARY OF THE INVENTION AND ADVANTAGES

The instant invention provides a method of forming an electronic article and the electronic article itself. The electronic article includes an optoelectronic semiconductor having a refractive index of 3.7±2 and a dielectric layer having a thickness of at least 50 μm and a refractive index of 1.4±0.1. The electronic article also includes a gradient refractive index coating (GRIC) that is disposed on the optoelectronic semiconductor and sandwiched between the optoelectronic semiconductor and the dielectric layer. The gradient refractive index coating has a thickness of from 50 to 400 nm and a refractive index varying along the thickness from 2.7±0.7 at a first end to 1.5±0.1 at a second end adjacent to the dielectric layer. The gradient refractive index coating also includes a gradient of a carbide and an oxycarbide along the thickness. Each of the carbide and the oxycarbide independently includes at least one of a silicon atom and a germanium atom. The method of forming the article includes the step of continuously depositing the gradient refractive index coating on the optoelectronic semiconductor using plasma-enhanced chemical vapor deposition in a dual frequency configuration. The method also includes the step of subsequently disposing the dielectric layer on the gradient refractive index coating.

The continuous deposition of the gradient refractive index coating forms the gradient of the carbide and oxycarbide and minimizes a number of optical interfaces in the electronic article thereby reducing reflection and providing the electronic article with increased functionality across a variety of applications. The gradient also reduces both reflection and absorption of light thereby allowing greater amounts of light to reach, or leave, the optoelectronic device and, in turn, increasing the efficiency of the electronic article.

### BRIEF DESCRIPTION OF THE DRAWINGS

Other advantages of the present invention will be readily appreciated, as the present invention becomes better understood by reference to the following detailed description when considered in connection with the accompanying drawings wherein the components are not necessarily illustrated to scale relative to each other and wherein:

FIG. 1A is a side view of one embodiment of the electronic article of the instant invention including a dielectric layer disposed directly on an optoelectronic semiconductor and sandwiched between the optoelectronic semiconductor and a gradient refractive index coating;

FIG. 1B is a side view of another embodiment of the electronic article wherein an inorganic layer is disposed directly on the optoelectronic semiconductor and the dielectric layer is disposed on, but spaced apart from, the optoelectronic semiconductor and sandwiched between the optoelectronic semiconductor and the gradient refractive index coating;

FIG. 1C is a side view of the electronic article of FIG. 1A further including the substrate and the superstrate;

FIG. 2A is a cross-sectional view of one embodiment of a photovoltaic cell module relating to FIG. 1A wherein the optoelectronic semiconductor is further defined as a photovoltaic cell and the dielectric layer is disposed directly on the photovoltaic cell and sandwiched between the photovoltaic cell and the gradient refractive index coating;

FIG. 2B is a cross-sectional view of another embodiment of a photovoltaic cell module relating to FIG. 1B wherein the optoelectronic semiconductor is further defined as a photovoltaic cell, the inorganic layer is disposed directly on the photovoltaic cell, and the dielectric tie layer is disposed on, but spaced apart from, the photovoltaic cell and sandwiched between the photovoltaic cell and the gradient refractive index coating;

FIG. 2C is a side view of the photovoltaic cell module of FIG. 1A wherein the optoelectronic semiconductor is further defined as a photovoltaic cell;

FIG. 3A is a cross-sectional view of a series of photovoltaic cell modules of FIG. 2C that are electrically connected and arranged as a photovoltaic array;

FIG. 3B is a magnified cross-sectional view of the series of photovoltaic cell modules of FIG. 3A that are electrically connected and arranged as a photovoltaic array;

FIG. 4 is a schematic of a typical plasma enhanced chemical vapor deposition (PECVD) apparatus illustrating first, second, and third electrodes and a plasma formed therebetween;

FIG. 5 is an image of a continuous gradient formed using the method of this invention that increases progressively from 100% carbide to 100% oxycarbide;

FIG. 6 is a line graph illustrating deposition rate of plasma, an extrapolation of the deposition rate, refractive index of the GRIC changing as a function of oxygen flow rate in a PECVD process, and an extrapolation of the changing refractive index;

FIG. 7 is an infrared spectral graph illustrating absorbance and generation of Si—O bonds in the GRIC as a function of wave number that changes as oxygen is introduced;

FIG. 8 is a line graph illustrating percentage light transmittance of uncoated glass as compared to one embodiment of the GRIC, as a function of wavelength;

FIG. 9 is a line graph illustrating reflection of layers of various embodiments of the electronic article of this invention as a function of wavelength;

FIG. 10 is a line graph illustrating refractive index as a function of thickness of various embodiments of the GRIC; and

FIG. 11 illustrates approximate lattice structures of hydrogenated silicon carbide (SiC:H) and hydrogenated silicon oxycarbide (SiOC:H).

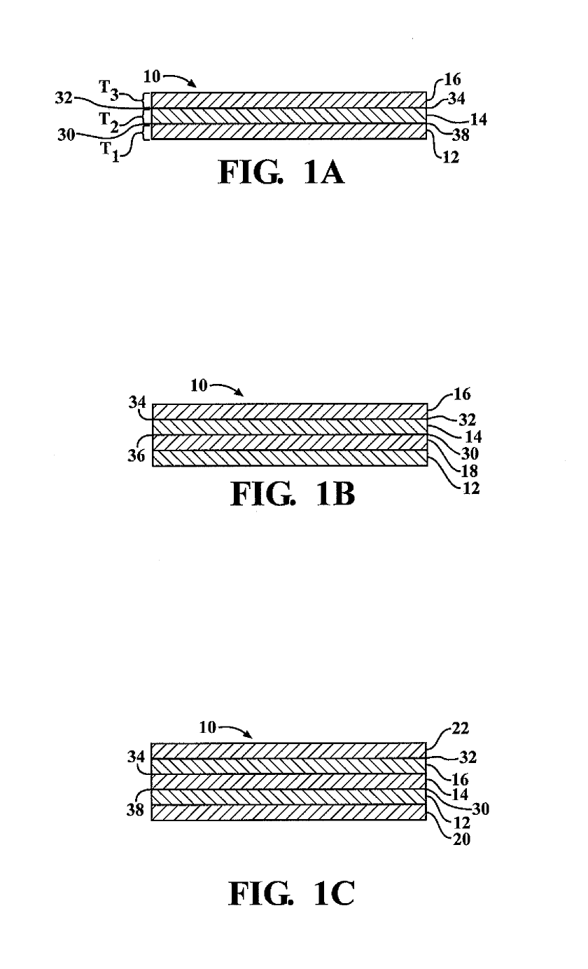

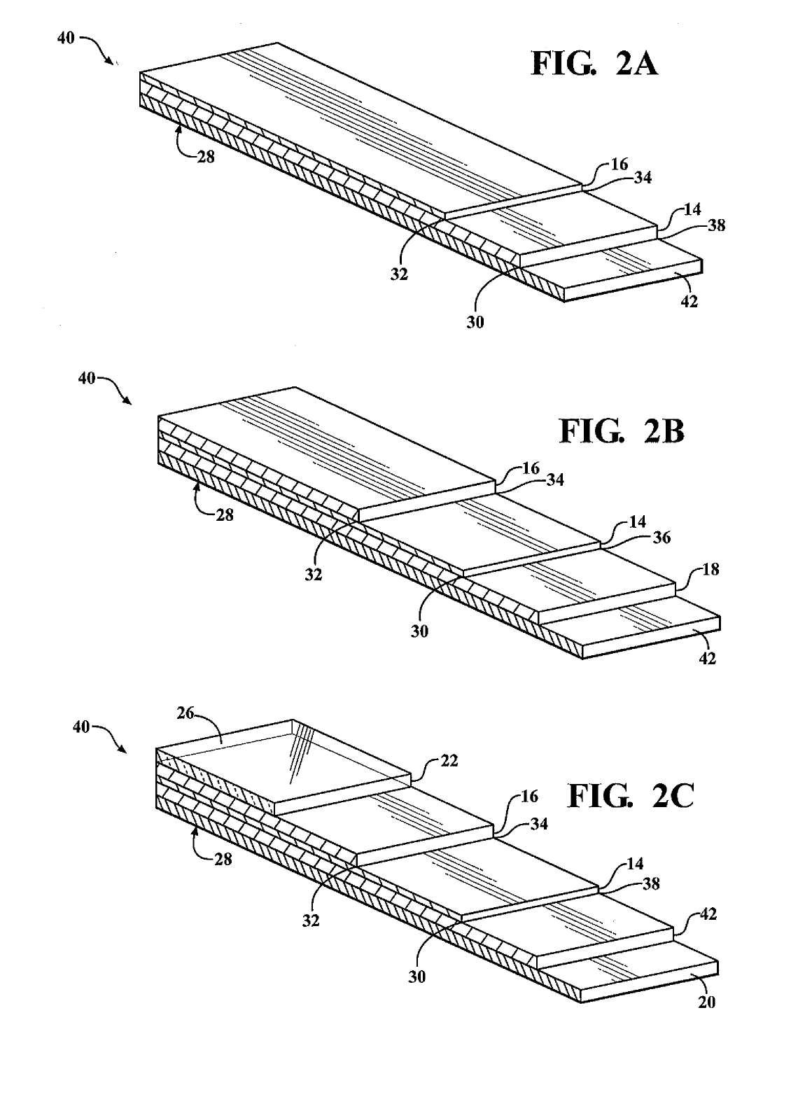

### DETAILED DESCRIPTION OF THE INVENTION

The present invention provides an electronic article (10) and a method of forming the article. The electronic article (10) typically has a light reflection of less than 15, 10, 7, 5, 4, 3, 2, or 1% over a range of wavelengths of from about 400 to about 1200 nanometers. The light reflection is typically measured using a spectrophotometer and/or an ellipsometer such as a Cary 5000 UV-Vis-NIR spectrophotometer commercially available from Varian. The electronic article (10) is not particularly limited and can be further defined as a photovoltaic cell module (40) and/or solid state lighting including, for example, light emitting diodes (LEDs), as described in greater detail below.

### Optoelectronic Semiconductor:

The electronic article (10) of this invention includes an optoelectronic semiconductor (12) that has a refractive index of about 3.7±about 2, about 1.5, or about 1, as determined using a refractometer. The optoelectronic semiconductor (12) is typically a device that sources and/or detects and controls light such as visible light, gamma rays, x-rays, ultraviolet rays, and infrared rays. Optoelectronic semiconductors (12) typically operate as electrical-to-optical or optical-to-electrical transducers. Typical, but non-limiting optoelectronic semiconductors (12) include photodiodes including solar cells, phototransistors, photomultipliers, integrated optical circuit (IOC) elements, photoresistors, photoconductive camera tubes, charge-coupled imaging devices, injection laser diodes, quantum cascade lasers, light-emitting diodes, photoemissive camera tubes, and the like. In one embodiment, the optoelectronic semiconductor (12) is further defined as a solar cell. In another embodiment, the optoelectronic semiconductor (12) is further defined as a light emitting diode. The optoelectronic semiconductor (12) is not particularly limited in size or shape. However, in various embodiments, the optoelectronic semiconductor (12) is further defined as an OLED and has a thickness of from 0.2 to 2.0, of from 0.4 to 1.8, of from 0.6 to 1.6, of from 0.8 to 1.4, or of from 1.0 to 1.2, mm. In other embodiments, the optoelectronic semiconductor (12) is further defined as a solar cell and has a thickness of from 1 to 500, from 1 to 5, from 1 to 20, from 300 to 500, from 50 to 250, from 100 to 225, or from 175 to 225, micrometers. It is also contemplated that the thickness may vary from the values and/or range of values above by ±5%, ±10%, ±15%, ±20%, ±25%, ±30%, etc.

The optoelectronic semiconductor (12) is not particularly limited and may be any known in the art. Typically, the optoelectronic semiconductor (12) has an electrical conductivity of from about 10³ S/cm to about 10⁻⁸ S/cm. In one embodiment, the optoelectronic semiconductor (12) includes silicon. In other embodiments, the optoelectronic semiconductor (12) includes arsenic, selenium, tellurium, germanium, gallium arsenide, silicon carbide, and/or elements from Groups IV, III-V, II-VI, I-VII, IV-VI, V-VI, and II-V, and may be of p- or n-type. It is contemplated that the optoelectronic semiconductor (12) may be disposed on a substrate (20), as described in greater detail below, using chemical vapor deposition (CVD). Alternatively, the optoelectronic semiconductor (12) may be as described in PCT/US09/01623, PCT/US09/01621, and/or PCT/US09/62513, each of which is expressly incorporated herein by reference.

### Dielectric Layer:

The electronic article (10) also includes a dielectric layer (16) that is disposed on the optoelectronic semiconductor (12). The terminology “disposed on” includes the dielectric layer (16) disposed on and in direct contact with the optoelectronic semiconductor (12). This terminology also includes the dielectric layer (16) spaced apart from the optoelectronic semiconductor (12) yet still disposed thereon.

The dielectric layer (16) has a refractive index of about 1.4±about 0.1. In other embodiments, the dielectric layer (16) has a refractive index of about 1.4±about 0.2, 0.3, 0.4, or 0.5. In another embodiment, the refractive index of the dielectric layer (16) is approximately matched to the refractive index of the gradient refractive index coating, described in greater detail below. The dielectric layer (16) also typically has a light transparency of at least 45, 50, 55, 60, 65, 70, 75, 80, 85, 90, 95, 96, 97, 98, 99, or 99.5, percent. In one embodiment, the dielectric layer (16) has a light transparency of about 100 percent.

The dielectric layer (16) also has a thickness (T₂) of at least 50 μm. In various embodiments, the dielectric layer (16) has a thickness (T₂) of at least 55, 60, 65, 70, 75, 80, 85, 90, 95, 100, 105, 110, 115, 120, or 125, μm. Alternatively, the dielectric layer (16) may have thickness (T₂) of from 50 to 150, from 60 to 140, from 70 to 130, from 80 to 120, or from 90 to 110, μm. In another embodiment, the dielectric layer (16) has a thickness (T₂) of about 100 μm. In various embodiments, the dielectric layer (16) has a thickness (T₂) that is about the same or longer than the coherence length of the solar spectrum, whether visible light, UV light, IR light, etc. Without intending to be bound by any particular theory, it is believed that this thickness (T₂) minimizes interference effects due to an optical path length greater than the coherence length of natural light, e.g. sunlight. If the dielectric layer (16) is overly thinned, increased interference may occur which may cause coloring and/or spectral effects. Of course, the invention is not limited to these thicknesses or ranges thereof and the thickness (T₂) of the dielectric layer (16) may be any value or range of values, both whole and fractional, within those ranges and values described above. It is also contemplated that the thickness (T₂) of the dielectric layer (16) may vary from the values and/or range of values above by ±5%, ±10%, ±15%, ±20%, ±25%, ±30%, etc.

The dielectric layer (16) is not particularly limited and may be formed from and/or include an inorganic compound, and organic compound, or a mixture of organic and inorganic compounds. These compounds may or may not require curing. Alternatively, the dielectric layer (16) may be formed from and/or include metals, polymers, plastics, silicones, glass, sapphire, and the like so long as the refractive index is as described above. In one embodiment, the dielectric layer (16) is further defined as ethylene vinyl acetate (EVA). In another embodiment, the dielectric layer (16) is further defined as glass. In still another embodiment, the dielectric layer (16) is further defined as a silicone. Alternatively, the dielectric layer (16) may be further defined as an acrylate. Typically, the dielectric layer (16) is transparent.

The dielectric layer (16) may be formed from a curable composition including silicon atoms. In one embodiment, the curable composition includes a hydrosilylation curable PDMS. In other embodiment, the dielectric layer (16) may be as described in PCT/US09/01623, PCT/US09/01621, and/or PCT/US09/62513, each of which is expressly incorporated herein by reference.

As first introduced above, the electronic article (10) may include multiple dielectric layers (16), e.g. a second and/or a third dielectric layer (16). Any additional dielectric layer (16) may be the same or different from the dielectric layer (16) described above. In one embodiment, the electronic article (10) includes the dielectric layer (16) described above and a second dielectric layer (16). Further, the dielectric layer (16) may be transparent to UV and/or visible light and the second (or additional) dielectric layers may be transparent to UV and/or visible light, impermeable to light, or opaque.

### Gradient Refractive Index Coating (GRIC):

The electronic article (10) also includes a gradient refractive index coating (14) (GRIC) disposed on the optoelectronic semiconductor (12). Just as above, the terminology “disposed on” includes the GRIC (14) disposed on and in direct contact with the optoelectronic semiconductor (12). This terminology also includes the GRIC (14) spaced apart from the optoelectronic semiconductor (12) yet still disposed thereon.

The GRIC (14) has a thickness (T₃) of from 50 to 400 nanometers which is typically chosen to reduce light absorption. In various embodiments, the GRIC (14) has a thickness (T₃) of from 60 to 390, from 70 to 380, from 80 to 370, from 90 to 360, from 100 to 350, from 110 to 340, from 120 to 330, from 120 to 320, from 130 to 310, from 140 to 300, from 150 to 290, from 160 to 280, from 170 to 270, from 180 to 260, from 190 to 250, from 200 to 240, or from 210 to 230, nm. Of course, the invention is not limited to these thicknesses or ranges thereof and the thickness (T₃) of the GRIC (14) may be any value or range of values, both whole and fractional, within those ranges and values described above. It is also contemplated that the thickness (T₃) of the GRIC (14) may vary from the values and/or range of values above by ±5%, ±10%, ±15%, ±20%, ±25%, ±30%, etc.

The GRIC (14) has a refractive index that varies along the thickness. Typically, the GRIC (14) has a refractive index at a first end (30) of about 2.7±0.7. The first end (30) may be further defined as an interface (38) between the GRIC (14) and the optoelectronic semiconductor (12). Alternatively, the first end (30) may be further defined as an interface (36) between the GRIC (14) and an inorganic layer (18), which is described in greater detail below. The GRIC (14) also typically has a refractive index at the second end (32) of about 1.5±0.1 (e.g. adjacent to the dielectric layer (16)). In other words, the second end (32) may be further defined as an interface (34) between the GRIC (14) and the dielectric layer (16).

The refractive index of the GRIC at a particular point along the thickness is determined by instantaneous deposition conditions. This refractive index corresponds to the refractive index of a homogeneous coating deposited using identical, but static, deposition conditions for the full coating thickness.

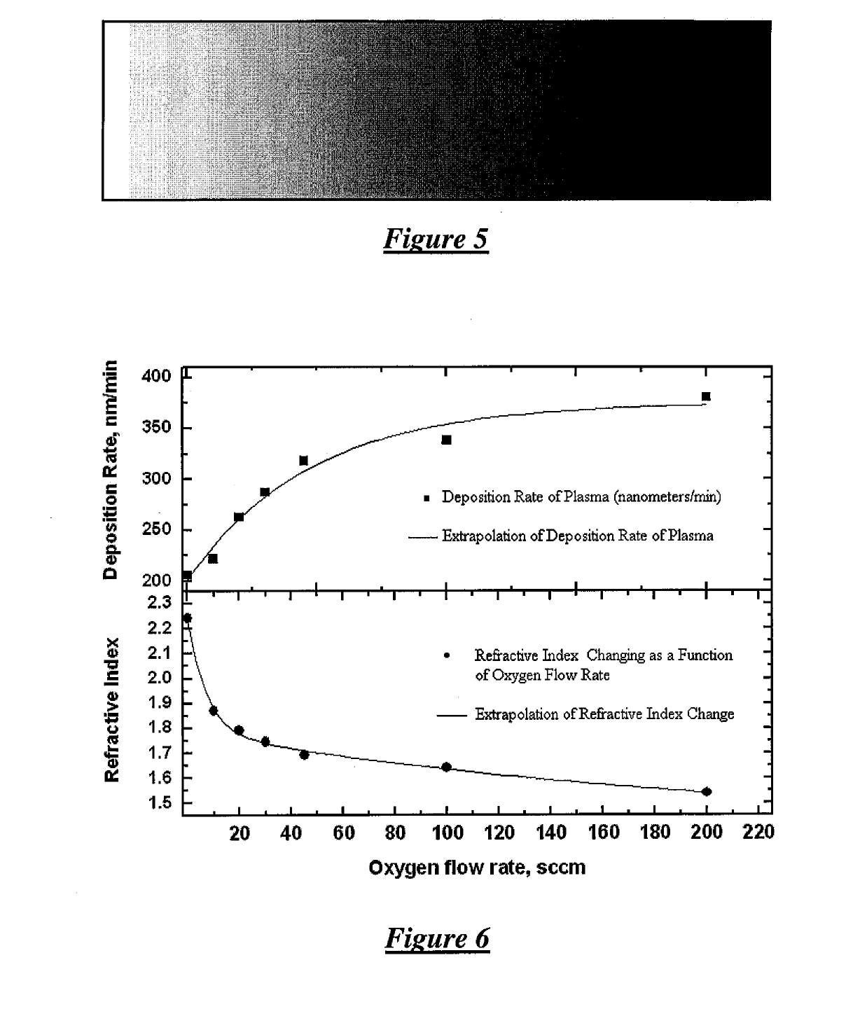

In one embodiment, the GRIC (14) includes a gradient of the refractive indices described above. In another embodiment, the GRIC (14) includes a gradient of a carbide and an oxycarbide along the thickness. In still another embodiment, the GRIC (14) includes both a gradient of the refractive indices and of the carbide and oxycarbide. The gradients of the refractive indices and of the carbide and oxycarbide may independently be continuous (e.g. uninterrupted and/or consistently changing) or stepped, e.g. discontinuous or changing in one or more steps. The terminology “gradient” typically refers to a graded change in the magnitude of the refractive indices and/or the carbide and oxycarbide, e.g. from lower to higher values or vice versa. In one embodiment, the gradient may be further defined as a vector field which points in the direction of the greatest rate of increase and whose magnitude is the greatest rate of change. In another embodiment, the gradient may be further defined as a series of 2 dimensional vectors at points on the GRIC (14) with components given by the derivatives in horizontal and vertical directions. At each point on the GRIC (14), the vector points in the direction of largest possible intensity increase, and the length of the vector corresponds to the rate of change in that direction. A non-limiting example of a 2-dimensional gradient is set forth in FIG. 5.

Referring back to the carbide and oxycarbide, each of the carbide and the oxycarbide independently include at least one of a silicon atom (Si) and a germanium atom (Ge), e.g. at least one of a silicon atom and/or a germanium atom. In one embodiment, carbide is further defined as hydrogenated silicon carbide (SiC:H) and the oxycarbide is further defined as hydrogenated silicon oxycarbide (SiOC:H) (see, for example, FIG. 11). In another embodiment, the carbide is further defined as hydrogenated germanium carbide (GeC:H) and the oxycarbide is further defined as hydrogenated germanium oxycarbide (GeOC:H). In still another embodiment, the carbide is further defined as hydrogenated silicon germanium carbide (SiGeC:H) and the oxycarbide is further defined as hydrogenated silicon germanium oxy-carbide (SiGeOC:H).

The gradient may be formed by any method or process known in the art. However, the method typically used to form the GRIC (14) of this invention is free of monosilanes. In one embodiment that is described in greater detail below, the gradient is formed using plasma-enhanced chemical vapor deposition (PECVD). In alternative embodiments, the gradient is formed using electrical heating, hot filament processes, UV irradiation, IR irradiation, microwave irradiation, X-ray irradiation, electronic beams, laser beams, plasma, RF, radio frequency plasma enhanced chemical vapor deposition (RF-PECVD), electron-cyclotron-resonance plasma-enhanced chemical vapor deposition (ECR-PECVD), inductively coupled plasma enhanced chemical vapor deposition (ICP-ECVD), plasma beam source plasma enhanced chemical vapor deposition (PBS- PECVD), and/or combinations thereof.

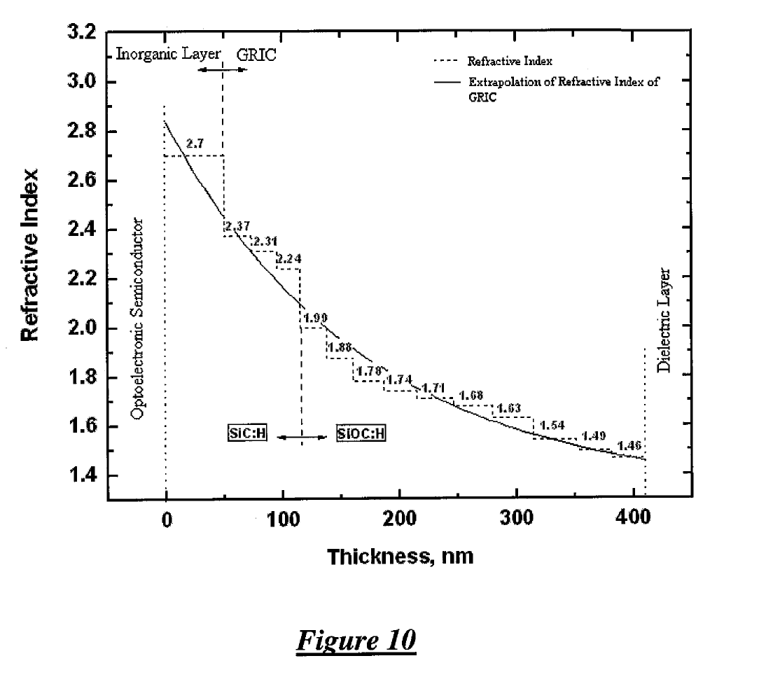

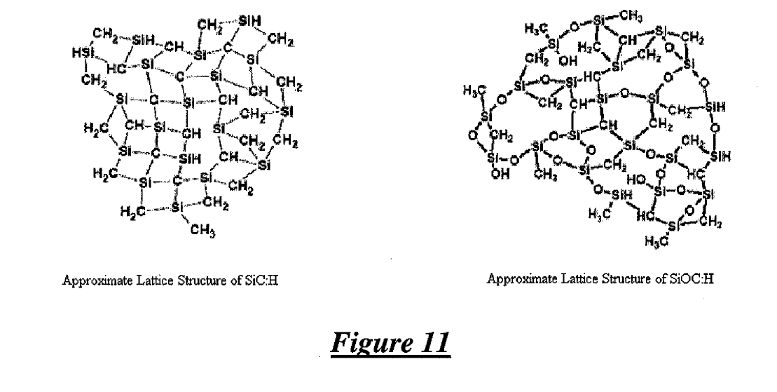

In additional non-limiting embodiments of this invention, the GRIC (14) has a continuous gradient with one extreme of the gradient selected to approximately match the refractive index of the optoelectronic semiconductor (12). In this embodiment, the index of refraction of the GRIC (14) typically smoothly shifts from approximately matching the refractive index of the optoelectronic semiconductor (12) to a refractive index that approximately matches that of the dielectric layer (16) to avoid significant discontinuity in optical characteristics at interfaces therebetween. In one embodiment, the GRIC (14) has hydrogenated silicon carbide (SiC:H) at the interface with the optoelectronic semiconductor (12) and then the continuous gradient gradually changes to hydrogenated silicon oxycarbide (SiOC:H) with the highest oxygen content near the interface with the dielectric layer (16). Without intending to be bound by any particular theory, it is believed that changing composition and/or density of the GRIC (14) along with grading the optical impedance of the GRIC (14) provides a smooth transition between the optoelectronic semiconductor (12) and the dielectric layer (16) approximately matching the optical parameters of each at the relevant interfaces (see, for example, FIG. 10). Moreover, in one related embodiment, the dielectric layer (16) includes an organosilicon material such as crosslinked silicone elastomer such as, but not limited to, poly(dimethylsiloxane) (PDMS). In this embodiment, the dielectric layer (16) is typically greater than 100 μm thick, which is the approximate coherence length of natural sunlight as well as most artificial light sources. Therefore, in this non-limiting embodiment, the dielectric layer (16) typically extends an optical path length beyond the coherence length, frustrating and minimizing any remaining interference effects. This is thought to improve light transmission across the interface and eliminate wavelength and angular dependence associated with the GRIC (14). In other non-limiting embodiments, the electronic article (10) includes the inorganic layer (18) which is chosen to reduce the Fresnel reflection coefficient(s) at the interface of the GRIC (14) and the optoelectronic semiconductor (12).

### Inorganic Layer:

As first introduced above, the article may include the inorganic layer (18). In one embodiment, the inorganic layer (18) is disposed on the optoelectronic semiconductor (12) and sandwiched between the optoelectronic semiconductor (12) and the GRIC (14). The terminology “disposed on” includes the inorganic layer (18) disposed on and in direct contact with the optoelectronic semiconductor (12). This terminology also includes the inorganic layer (18) spaced apart from the optoelectronic semiconductor (12) yet still disposed thereon.

The inorganic layer (18) is not particularly limited and may include any inorganic (i.e., non-organic) element or compound known in the art. It is also contemplated that the inorganic layer (18) may include a content of organic compounds in addition to inorganic compounds. In one embodiment, the inorganic layer (18) includes silicon carbide. Without intending to be bound by any particular theory, it is believed that the inorganic layer (18) may be used to compatibilize the GRIC (14) and the optoelectronic semiconductor (12). It is contemplated that the inorganic layer (18) may have a refractive index within 1, 2, 3, 4, 5, 10, 15, 20, or 25 percent to that of the GRIC (14) and/or to that of the optoelectronic semiconductor (12). Of course, the invention is not limited to these refractive indices or ranges thereof and the refractive index of the inorganic layer (18) may be any value or range of values, both whole and fractional, within those ranges and values described above. It is also contemplated that the refractive index of the inorganic layer (18) may vary from the values and/or range of values above by ±5%, ±10%, ±15%, ±20%, ±25%, ±30%, etc.

### Substrate and Superstrate:

The electronic device may also include a substrate (20) and/or a superstrate (22). Typically, the substrate (20) provides protection to a rear surface (28) of the electronic device while a superstrate (22) typically provides protection to a front surface (26) of the electronic device. The substrate (20) and the superstrate (22) may be the same or may be different and each may independently include any suitable material known in the art. Typically, the substrate (22) has a light transparency of at least 45, 50, 55, 60, 65, 70, 75, 80, 85, 90, 95, 96, 97, 98, 99, or 99.5, percent. In one embodiment, the substrate (22) has a light transparency of about 100 percent.

The substrate (20) and/or superstrate (22) may be soft and flexible or may be rigid and stiff. Alternatively, the substrate (20) and/or superstrate (22) may include rigid and stiff segments while simultaneously including soft and flexible segments. The substrate (20) and/or superstrate (22) may be transparent to light, may be opaque, or may not transmit light (i.e., may be impervious to light). In one embodiment, the substrate (20) and/or superstrate (22) include glass. In another embodiment, the substrate (20) includes metal foils, semiconductors, polyimides, ethylene-vinyl acetate copolymers, and/or organic fluoropolymers including, but not limited to, ethylene tetrafluoroethylene (ETFE), Tedlar®, polyester/Tedlar®, Tedlar®/polyester/Tedlar®, polyethylene terephthalate (PET) alone or coated with silicon and oxygenated materials (SiO_{X}), and combinations thereof. The substrate (2) may alternatively be further defined as a PET/SiOₓ-PET/A1 substrate (20), wherein x has a value of from 1 to 4. In one embodiment, the superstrate (22) can be further defined as including one or more of the aforementioned compounds so long as the superstrate has a has a light transparency of at least 45 percent.

The substrate (20) and/or superstrate (22) may be load bearing or non load bearing and may be included in any portion of the electronic device. Typically, the substrate (20) is load bearing. The substrate (20) may be a “bottom layer” of the electronic device that is typically positioned behind the optoelectronic semiconductor (12) and serves as mechanical support. Alternatively, the electronic device may include a second or additional substrate (20) and/or superstrate (22). The substrate (2) may be the bottom layer of the electronic device (and an active portion of the electronic device) while a second substrate (20) may be the top layer and function as the superstrate (22). Typically, the second substrate (20) (e.g. a second substrate (20) functioning as a superstrate (22)) is transparent to the solar spectrum (e.g. visible light) and is positioned on top of the substrate (20). The second substrate (20) may be positioned in front of a light source. The second substrate (20) may be used to protect the electronic device from environmental conditions such as rain, show, and heat. Most typically, the second substrate (20) functions as a superstrate (22) and is a rigid glass panel that is transparent to sunlight and is used to protect the front surface (26) of the electronic device. The substrate (20) and/or superstrate (22) typically have a thickness of from 50 to 500, of from 100 to 225, or of from 175 to 225, micrometers. It is also contemplated that the thickness of the substrate (20) and/or superstrate (22) may vary from the values and/or range of values above by ±5%, ±10%, ±15%, ±20%, ±25%, ±30%, etc. Alternatively, the superstrate (20) and/or superstrate (22) may be as described in PCT/US09/01623, PCT/US09/01621, and/or PCT/US09/62513, each of which is expressly incorporated herein by reference.

### Tie Layers:

In addition, the electronic article (10) may also include one or more tie layers (not shown in the Figures) which may adhere one or more layers to each other. The one or more tie layers may be disposed on the substrate (20) to adhere the optoelectronic semiconductor (12) to the substrate (20). In various embodiments, the electronic article (10) includes multiple tie layers , e.g. first, second, and/or a third tie layer. Any second, third, or additional tie layer may be the same or different from the (first) tie layer. Thus, any second, third or additional tie layer may be formed from the same material or from a different material than the (first) tie layer. The second tie layer may be disposed on the (first) tie layer and/or may be disposed on the optoelectronic semiconductor (12). The one or more tie layers are each typically transparent to UV and/or visible light. However, one or more of the tie layers may be impermeable to light or opaque. In one embodiment, the tie layer has high transmission across visible wavelengths, long term stability to UV and provides long term protection to the optoelectronic semiconductor (12). In this embodiment, there is no need to dope the substrate (20) with cerium due to the UV stability of the tie layer.

The tie layers are not particularly limited in thickness but typically have a thickness of from 1 to 50, more typically from 3 to 30, and most typically of from 4 to 15, mils. In various embodiments, the tie layers have a thickness of from 1 to 30, from 1 to 25, from 1 to 20, from 3 to 17, from 5 to 10, from 5 to 25, from 10 to 15, from 10 to 17, from 12 to 15, from 10 to 30, or from 5 to 20, mils. Of course, the invention is not limited to these thicknesses or ranges thereof and the thickness of the tie layers may be any value or range of values, both whole and fractional, within those ranges and values described above. It is also contemplated that the thickness of the tie layers may vary from the values and/or range of values above by ±5%, ±10%, ±15%, ±20%, ±25%, ±30%, etc. Alternatively, the tie layer(s) may be as described in PCT/US09/01623, PCT/US09/01621, and/or PCT/US09/62513, each of which is expressly incorporated herein by reference.

### Photovoltaic Cell Modules:

As first described above, the article (10) is not particularly limited and can be further defined as a photovoltaic cell module (40). As is known in the art, photovoltaic cell modules (4) (hereinafter referred to as “modules”) convert light energy into electrical energy due to a photovoltaic effect. More specifically, modules (4) perform two primary functions. A first function is photogeneration of charge carriers such as electrons and holes in optoelectronic semiconductors (12), as are described in greater detail below. The second function is direction of the charge carriers to a conductive contact to transmit electricity.

In one embodiment, the electronic article (10) is further defined as a module (40) that includes a photovoltaic cell (42) as the optoelectronic semiconductor (12), the dielectric layer (16), and the GRIC (14) that includes a gradient of hydrogenated silicon carbide (SiC:H) and hydrogenated silicon oxycarbide (SiOC:H). The module (40) may also include one or more of the substrate (20), superstrate (22), or layers described above. In still other embodiments, the gradient of the photovoltaic cell (42) is as described above.

In one embodiment, the photovoltaic cell (42) is disposed on the substrate (2) via chemical vapor deposition or sputtering. Typically, in this embodiment, no tie layer is required between the photovoltaic cell (42) and the substrate (20). This embodiment is typically referred to as a “thin-film” application. After the photovoltaic cell (42) is disposed on the substrate (20) using sputtering or chemical vapor deposition processing techniques, one or more electrical leads (not shown in the Figures) may be attached to the photovoltaic cell (42). The dielectric layer (16) and/or the curable composition may then be applied over the electrical leads.

The photovoltaic cell (42) typically has a thickness of from 1 to 500, from 1 to 5, from 1 to 20, from 300 to 500, from 50 to 250, from 100 to 225, or from 175 to 225, micrometers. The photovoltaic cell (42) also typically has a length and width (not shown in the Figures) of from 100×100 cm to 200×200 cm. In one embodiment, the photovoltaic cell (42) has a length and width of 125 cm each. In another embodiment, the photovoltaic cell (42) has a length and width of 156 cm each. Of course, the invention is not limited to these thicknesses or ranges thereof and the thickness of the photovoltaic cell (42) may be any value or range of values, both whole and fractional, within those ranges and values described above. It is also contemplated that the thickness of the photovoltaic cell (42) may vary from the values and/or range of values above by ±5%, ±10%, ±15%, ±20%, ±25%, ±30%, etc.

The photovoltaic cell (42) may include large-area, single-crystal, single layer p-n junction diodes. These photovoltaic cells (42) are typically made using a diffusion process with silicon wafers. Alternatively, the photovoltaic cell (42) may include thin epitaxial deposits of (silicon) semiconductors on lattice-matched wafers. In this embodiment, the epitaxial photovoltaics may be classified as either space or terrestrial and typically have AM0 efficiencies of from 7 to 40%. Further, the photovoltaic cell (42) may include quantum well devices such as quantum dots, quantum ropes, and the like, and also include carbon nanotubes. Without intending to be limited by any particular theory, it is believed that these types of photovoltaic cells (42) can have up to a 45% AM0 production efficiency.

The photovoltaic cell (42) may include amorphous silicon, monocrystalline silicon, polycrystalline silicon, microcrystalline silicon, nanocrystalline silica, cadmium telluride, copper indium/gallium selenide/sulfide, gallium arsenide, polyphenylene vinylene, copper phthalocyanine, carbon fullerenes, and combinations thereof in ingots, ribbons, thin films, and/or wafers. The photovoltaic cell (42) may also include light absorbing dyes such as ruthenium organometallic dyes. Most typically, the photovoltaic cell (42) includes monocrystalline and polycrystalline silicon. It is also contemplated that any part of the description of the photovoltaic cell (42) of this embodiment may also apply to any one or more of the optoelectronic devices described above.

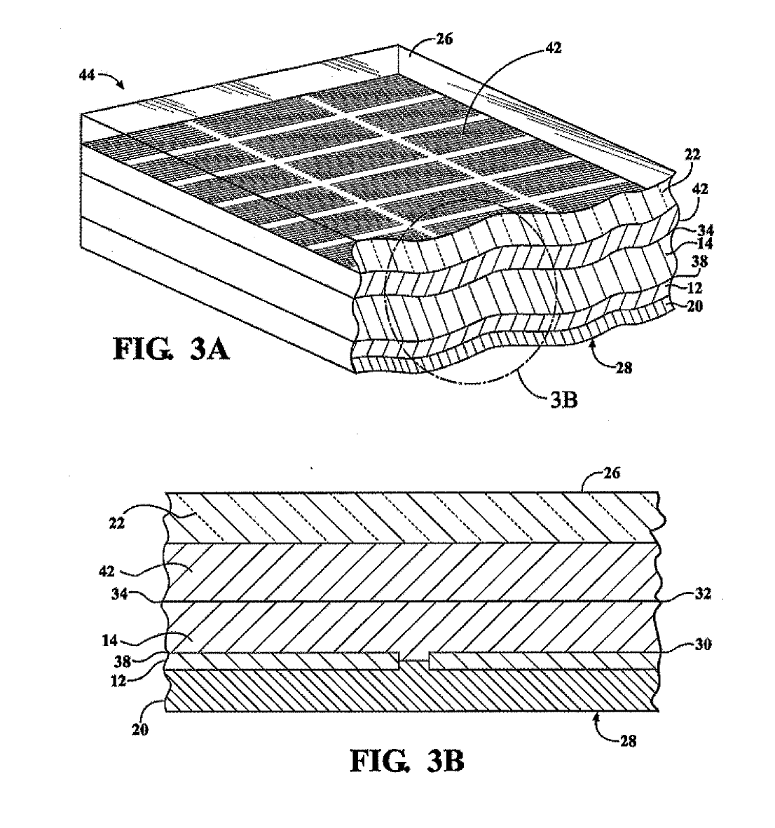

The module (40) of the instant invention can be used in any industry including, but not limited to, automobiles, small electronics, remote area power systems, satellites, space probes, radiotelephones, water pumps, grid-tied electrical systems, batteries, battery chargers, photoelectrochemical applications, polymer solar cell applications, nanocrystal solar cell applications, and dye-sensitized solar cell applications. The instant invention also provides a photovoltaic array (44), as shown in FIGS. 3. The photovoltaic array (44) includes at least two modules (4), or a series of modules (4), that are electrically connected. The photovoltaic array (44) of the instant invention may be planar or non-planar and typically functions as a single electricity producing unit wherein the modules (4) are interconnected in such a way as to generate voltage. Alternatively, the module (40) may be as described in PCT/US09/01623, PCT/US09/01621, and/or PCT/US09/62513, each of which is expressly incorporated herein by reference.

### Solid State Lighting:

As also described above, the article (10) can be further defined as a solid state light/lighting. Solid state lighting, such as LEDs, typically generate light in a forward biased state when electrons recombine with holes formed in optoelectronic semiconductors (12), as are described in greater detail below. When the electrons recombine, they release photons in a process typically described as electroluminescence. The solid state lighting can be used in any application including, but not limited to, instrument panels & switches, courtesy lighting, turn and stop signals, household appliances, vcr/dvd/ stereo/audio/video devices, toys/games instrumentation, security equipment, switches, architectural lighting, signage (channel letters), machine vision, retail displays, emergency lighting, neon and bulb replacement, flashlights, accent lighting full color video, monochrome message boards, in traffic, rail, and aviation applications, in mobile phones, PDAs, digital cameras, lap tops, in medical instrumentation, bar code readers, color & money sensors, encoders, optical switches, fiber optic communication, and combinations thereof.

### Method of Forming the Electronic Article:

The instant invention also provides a method of forming the electronic article (10). The method includes the step of continuously depositing the GRIC (14) on the optoelectronic semiconductor (12) using plasma-enhanced chemical vapor deposition (PECVD) in a dual frequency configuration. The terminology “continuously depositing” typically refers to the PECVD operating without interruption or with few interruptions. As is known in the art, continuous processes are very different from and approximately opposite to batch processes. Without intending to be bound by any particular theory, it is believed that the continuous operation of the PECVD minimizes or eliminates formation of additional optical interfaces in the GRIC (14) which allows a gradient to be formed with minimized reflection, absorption, and interference and also allows the electronic article (10) to be formed with increased flexibility and optimized optical properties.

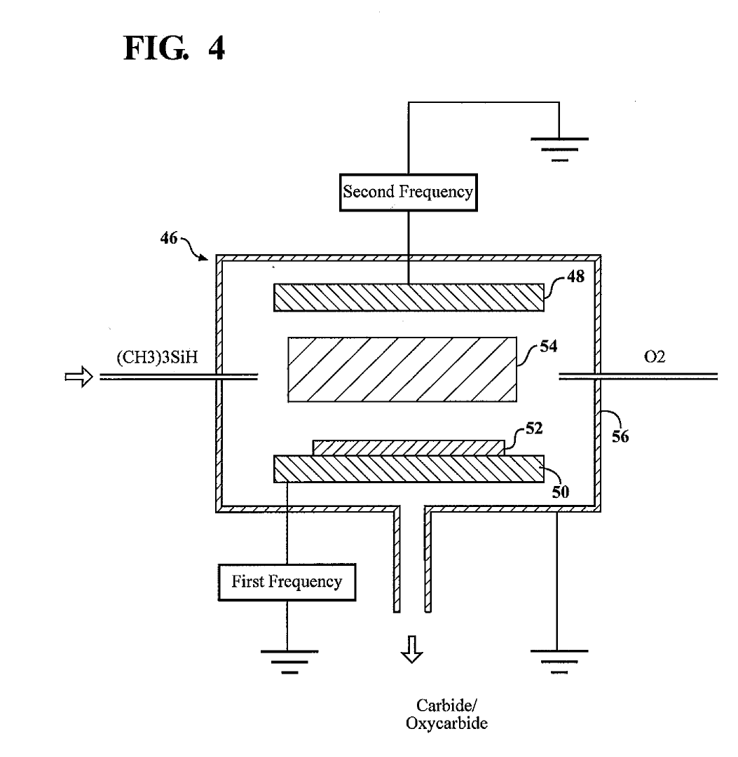

Typically, a PECVD system (46) is used in this method. One type of PECVD system is set forth in FIG. 4. Typical PECVD systems (46) mix precursor gasses in vacuum chambers and excite mixtures of the gases with radio frequency (RF) generators attached to electrodes to create plasmas of ionized gasses. An electrical potential difference between the plasmas and various substrates (2) accelerates ions towards the substrates (2) where they react, e.g. react to form the GRIC (14). Vacuum pressure, electrode power, temperature, and gas flow can be customized. In one embodiment, the PECVD system (46) includes a powered parallel electrode reactor (56) with electrodes powered with two generators. One generator is typically a standard RF generator (also called a high frequency power supply (e.g. 13.56 MHz)) with a power control range of 20 W to 600 W. The second generator is typically a middle to low frequency (e.g. 380 kHz) power supply with a power range of 20 W to 1000 W. The PECVD system may also include a third electrode (52).

In this method, the PECVD operates in a dual frequency configuration (e.g. mode). As is appreciated in the art, operation in the dual frequency configuration typically includes the operation of plasma enhanced chemical vapor deposition at a first and a second frequency simultaneously. The first frequency is typically between 50 and 400 kHz and can range from 60 to 390, from 70 to 380, from 80 to 370, from 90 to 360, from 100 to 350, from 110 to 340, from 120 to 330, from 130 to 320, from 140 to 310, from 150 to 300, from 200 to 290, from 210 to 280, from 220 to 270, from 230 to 260, or from 240 to 250, KHz. In one embodiment, the first frequency ranges between 70 and 400 KHz. In another embodiment, the first frequency is about 380 KHz. The second frequency is typically between 10 MHz and 1, or more than 1, GHz. In various embodiments, the second frequency ranges from 10 to 50, from 10 to 40, from 12 to 30, from 13 to 20, from 13 to 15, or from 13 to 14, MHz. In one embodiment, the second frequency is about 13.56 MHz. Of course, the invention is not limited to these frequencies or ranges thereof and each frequency may be any value or range of values, both whole and fractional, within those ranges and values described above. It is also contemplated that the frequencies may vary from the values and/or range of values above by ±5%, ±10%, ±15%, ±20%, ±25%, ±30%, etc.

The power of the electrodes used in the PECVD system and the instant method is not particularly limited and can be varied. In various embodiments, two electrodes are utilized wherein the power to each electrode may be varied independently. The power to a first electrode (48) typically ranges from 10 to 1000, from 10 to 600, from 50 to 200, from 80 to 160, from 90 to 150, from 100 to 140, from 110 to 130, or about 120, Watts. The first electrode (48) is typically associated with the first frequency described above. The power to a second electrode (5) typically ranges from 10 to 1000, from 10 to 600, from 200 to 400, from 210 to 390, from 220 to 380, from 230 to 370, from 240 to 360, from 250 to 350, from 260 to 340, from 270 to 330, from 280 to 320, from 290 to 310, or about 300, Watts. The second electrode (5) is typically associated with the second frequency described above. The invention is not limited to these powers or ranges thereof and the power may be any value or range of values, both whole and fractional, within those ranges and values described above. It is also contemplated that the power may vary from the values and/or range of values above by ±5%, ±10%, ±15%, ±20%, ±25%, ±30%, etc.

Without intending to be bound by any particular theory, it is believed that the second (e.g. high) frequency influences plasma density due to more efficient displacement current and sheath heating mechanisms. It is also believed that the first (e.g. low) frequency influences peak ion bombardment energy. Accordingly, the instant invention allows for separate adjustment and customization of ion bombardment energy and plasma density which also influences control of deposition stress and optical properties. In addition, this invention allows for greater control of lattice spacing of the GRIC (14) as well as stacking faults in crystal structure, control of pin holes and location of interstitial atoms, and minimization of deposition tension and stress.

In various embodiments, the step of continuously depositing the GRIC (14) includes one or more sub-steps. In one embodiment, the step of continuously depositing begins with a first sub-step of introducing a hydrogenated carbide, such as hydrogenated silicon carbide (SiC:H), hydrogenated germanium carbide (GeC:H), and/or hydrogenated silicon germanium carbide (SiGeC:H), into the plasma (54) at a high power (e.g. 500 Watts) and in the absence of oxygen. Without intending to be bound by theory, it is believed that this sub-step forms a first portion of the gradient with a high refractive index (e.g. greater than 2.7). In another embodiment, a second sub-step of increasing the pressure is utilized (e.g. increasing from 50 to 500 mTorr). Typically, increasing the pressure further hydrogenates the carbide and deceases the refractive index of the gradient that is being formed (e.g. from 2.4 to 1.4). In still another embodiment, a third sub-step is included and involves injecting oxygen into the plasma (54) to begin to form hydrogenated oxycarbides such as hydrogenated silicon oxycarbide (SiOC:H), hydrogenated germanium oxycarbide (GeOC:H), and/or hydrogenated silicon germanium oxycarbide (SiGeOC:H). In yet another embodiment, a fourth sub-step is included and involves decreasing power and increasing pressure to continue to form the immediately aforementioned compounds and decrease the refractive index as much as possible. In still other embodiments, the sub-steps involve one or more of the following, each of which may vary by ±5%, ±10%, ±15%, ±20%, ±25%, ±30%, etc.:

In various embodiments of the method of this invention, the total gas flow can range from 300 to 3,000, from 400 to 2,000, or from 450 to 850, standard cubic centimeters per minutes (sccm). The temperature can range from 20 to 400, from 30 to 250, or from 30 to 80° C. The pressure can range from 20 to 1000, from 50 to 500, or from 90 to 200, mTorr. It is to be appreciated that the invention is not limited to the aforementioned ranges. Any one or more of the parameters described immediately above may be any value or range of values, both whole and fractional, within those ranges and values described above. It is also contemplated that one or more of these parameters may vary from the values and/or range of values above by ±5%, ±10%, ±15%, ±20%, ±25%, ±30%, etc.

The method also includes the step of disposing the dielectric layer (16) on the GRIC (14). As described above, the dielectric layer (16) may be disposed directly on the GRIC (14) or may be spaced apart from the GRIC (14) and remain disposed upon. In one embodiment, the step of disposing the dielectric layer (16) is further defined as disposing the curable composition on the GRIC (14) and then either partially or completely curing the curable composition to form the dielectric layer (16). The curable composition may be applied using any suitable application method known in the art including, but not limited to, spray coating, flow coating, curtain coating, dip coating, extrusion coating, knife coating, screen coating, laminating, melting, pouring, and combinations thereof. In one embodiment, the dielectric layer (16) is formed from a liquid and the step of disposing the dielectric layer (16) is further defined as disposing a liquid on the GRIC (14) and curing the liquid on the GRIC (14) to form the dielectric layer (16). In another embodiment, the curable composition is supplied to a user as a multi-part system. A first part may include components (A), (B), and/or (D). A second part may include components (A), (B), and/or (C). The first and second parts may be mixed immediately prior to disposing the dielectric layer (16) on the substrate (20). Alternatively, each component and/or a mixture of components may be applied individually to the substrate (20) and react to form the dielectric layer (16) disposed on the substrate (20).

In one embodiment, the dielectric layer (16) is formed from the curable composition and the method further includes the step of partially curing, e.g. “pre-curing,” the curable composition to form the dielectric layer (16). In another embodiment, the method further includes the steps of applying the curable composition to the optoelectronic semiconductor (12) and curing the curable composition on the optoelectronic semiconductor (12) to form the dielectric layer (16). In one embodiment, the curable composition is cured prior to the step of disposing the dielectric layer (16) on the substrate (20). As set forth above, the curable composition may be cured at a temperature of from 25 to 200° C. The curable composition may also be cured for a time of from 1 to 600 seconds. Alternatively, the curable composition may be cured in a time of greater than 600 seconds, as determined by one of skill in the art.

The method may also include the step(s) of disposing the optoelectronic semiconductor (12) on the dielectric layer (16), the tie layer and/or the substrate (20). In this step or steps, the optoelectronic semiconductor (12) may also include the GRIC (14) disposed thereon. The optoelectronic semiconductor (12) can be disposed (e.g. applied) by any suitable mechanisms known in the art but are typically applied using an applicator in a continuous mode. Other suitable mechanisms of application include applying a force to the optoelectronic semiconductor (12) to more completely contact the optoelectronic semiconductor (12) and the dielectric layer (16), the tie layer and/or the substrate (20). In one embodiment, the method includes the step(s) of compressing the optoelectronic semiconductor (12) and the dielectric layer (16), the tie layer and/or the substrate (20). Compressing the optoelectronic semiconductor (12) and the dielectric layer (16), the tie layer and/or the substrate (20) is believed to maximize contact and maximize encapsulation, if desired. The step of compressing may be further defined as applying a vacuum to the optoelectronic semiconductor (12) and the dielectric layer (16), the tie layer and/or the substrate (20). Alternatively, a mechanical weight, press, or roller (e.g. a pinch roller) may be used for compression. Further, the step of compressing may be further defined as laminating. Still further, the method may include the step of applying heat to the electronic article (10) or any or all of the substrate (20), the GRIC (14), the optoelectronic semiconductor (12), dielectric layer (16), and/or the tie layer. Heat may be applied in combination with any other step or may be applied in a discrete step. The entire method may be continuous or batch-wise or may include a combination of continuous and batch-wise steps.

The step of disposing the optoelectronic semiconductor (12) on the dielectric layer (16) may be further defined as encapsulating at least part of the optoelectronic semiconductor (12) and/or the GRIC (14) with the dielectric layer (16). More specifically, the dielectric layer (16) may partially or totally encapsulate the optoelectronic semiconductor (12) and/or GRIC (14). Alternatively, the optoelectronic semiconductor (12) may simply be disposed on the dielectric layer (16) without any encapsulation. Without intending to be limited by any particular theory, and at least relative to photovoltaic cell module (40), it is believed that at least partial encapsulation encourages more efficient manufacturing and better utilization of the solar spectrum, thereby resulting in greater efficiency. Use of the dielectric layer (16) of the instant invention allows for production of an electronic article (10) with the optical and chemical advantages of silicone. Additionally, use of silicone allows for formation of UV transparent tie layers and/or dielectric layers (16) and may increase cell efficiency by at least 1-5%. Use of peroxide catalysts, as described above, may also provide increased transparency and increased cure speeds. Sheets of the curable composition including silicone may be used for assembly of the electronic article (10).

In yet another embodiment of the instant method, the dielectric layer (16) and/or the tie layer may be further defined as a film and the step of disposing may be further defined as applying the film, e.g. applying the film to one or more of the substrate (20), the GRIC (14), the optoelectronic semiconductor (12), and/or the superstrate (22). In this embodiment, the step of applying the film may be further defined as melting the film. Alternatively, the film may be laminated on one or more of the substrate (20), the GRIC (14), the optoelectronic semiconductor (12), and/or the superstrate (22).

In one embodiment, the method includes the step of laminating to melt the tie layer and/or the dielectric layer (16) and heat at least the substrate (20) and the optoelectronic semiconductor (12). After the step of laminating, in this embodiment, the method includes applying a protective seal and/or the frame to the electronic article (10), as first introduced above. In an alternative embodiment, the method includes the step of applying the optoelectronic semiconductor (12) to the substrate (20) by chemical vapor deposition. This step may be performed by any mechanisms known in the art. The method may also include the step of applying the additional tie layer , substrate (20), and/or superstrate (22).

### EXAMPLES

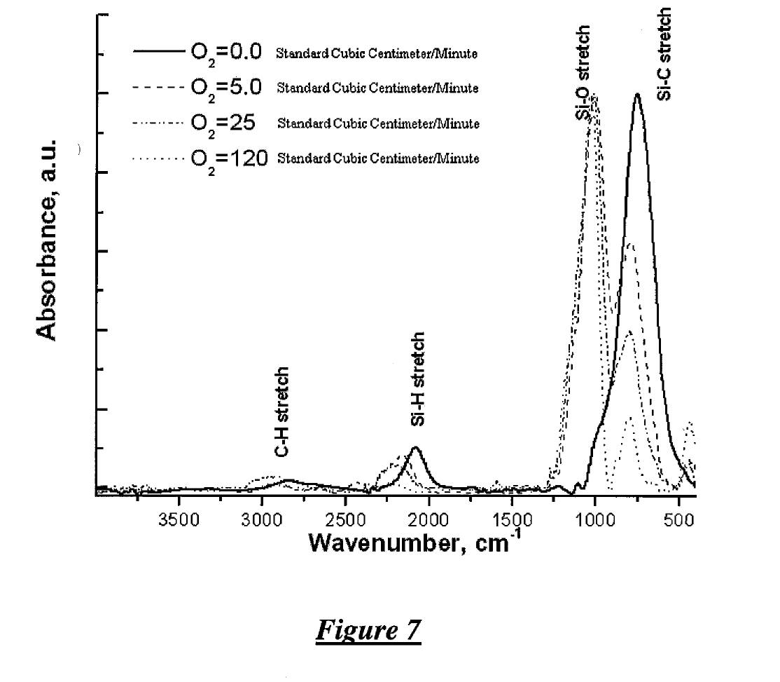

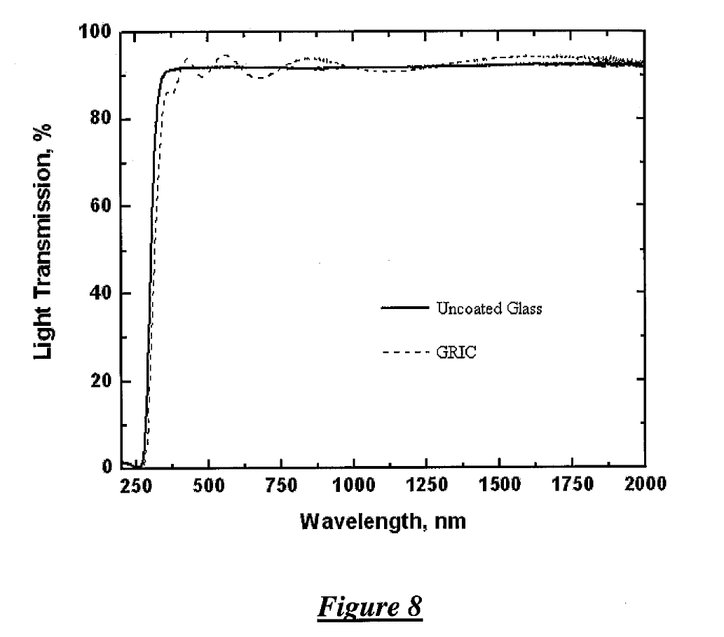

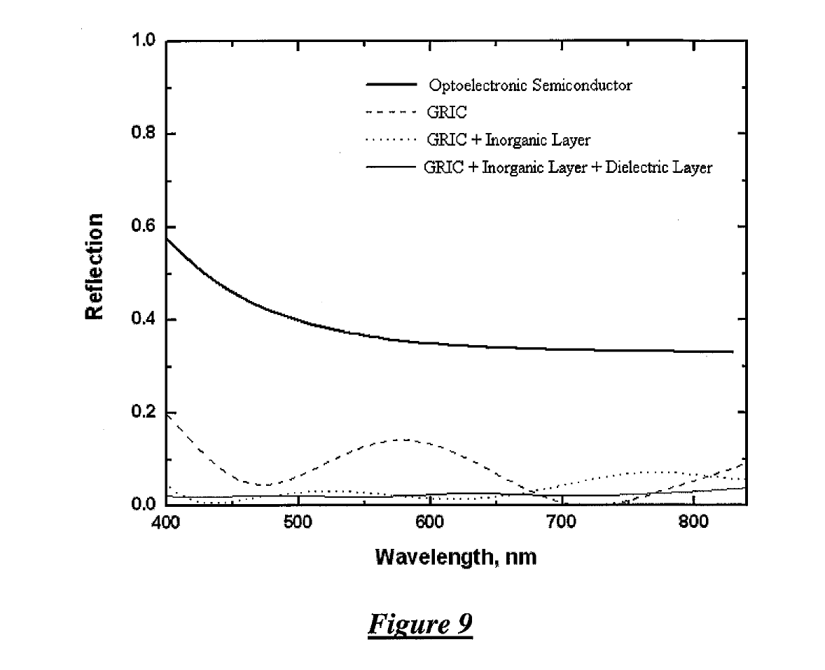

A series of electronic articles (Articles) are formed according to the method of the instant invention. Various samples of these Articles are then evaluated to determine a variety of parameters such as deposition rate and refractive index as a function of oxygen flow rate (as in FIG. 6), infrared absorbance as a function of wave number (as in FIG. 7), percentage light transmittance as a function of wavelength (as in FIG. 8), reflection as a function of wavelength (as in FIG. 9), and refractive index as a function of thickness of the GRIC (as in FIG. 10).

### First Series of Examples—General Procedure:

In a first series of Examples, monocrystalline silicon wafers as optoelectronic semiconductors are used as substrates of the Articles and are disposed thereon by chemical vapor deposition. The substrates are inserted into a parallel-plate capacitive plasma reactor operating in dual-frequency (DF) configuration. This reactor is commercially available from General Plasma, Inc. More specifically, the reactor is operated at room temperature using a pressure in the range of 50-200 mTorr, a first frequency of about 380 kHz at an electrode power in the range of about 50-200 W, a second frequency of about 13.56 MHz at an electrode power in the range of about 200-400 W.

A reactive gas mixture of trimethylsilane ((CH₃)₃SiH) and argon (Ar) is introduced into reactor and the PECVD process is initiated and forms the gradient refractive index coating (GRIC) on the monocrystalline silicon wafer. At the beginning of the PECVD process, hydrogenated silicon carbide (SiC:H) is deposited at a first end of the forming GRIC (i.e., at an interface with the monocrystalline silicon). As the PECVD process proceeds, pressure in the reactor is increased to form hydrogenated silicon carbide. Then, oxygen is injected into the plasma (54) to begin to form and deposit hydrogenated silicon oxycarbide (SiOC:H) at points extending away from the first end of the GRIC. Increasing amounts of oxygen are then injected into the plasma (54), power is decreased and pressure is increased to deposit gradually increasing amounts of hydrogenated silicon oxycarbide (SiOC:H) towards the second end of the GRIC (i.e., towards an interface with a subsequently disposed dielectric layer). Notably, the PECVD is continuously operated without interruption thereby minimizing a number of interfaces in the structure. After the GRIC is formed, a dielectric layer is disposed on the GRIC and monocrystalline silicon wafer immersing the glass slides in a solution of poly(dimethylsiloxane) (PDMS) and then allowing the PDMS to cure.

### Evaluation of Deposition Rate, Refractive Index, and Infrared Absorbance as a Function of Oxygen Flow Rate:

A series of Articles are formed using the General Procedure described immediately above. These Articles are formed while a flow rate of oxygen is varied in the reactor, while keeping all other parameters the same, which changes the composition and optical properties of the coatings disposed on the monocrystalline silicon wafer.

After formation, these Articles are analyzed using a spectroscopic ellipsometer to determine the refractive indices of the Articles as a function of oxygen flow rate. The ellipsometer is commercially available from Wollam Co., Inc. The Articles are also analyzed to measure thickness and determine deposition rate as a function of oxygen flow rate using spectroscopic ellipsometry as set forth in FIG. 6.

Complex refractive index, n*=n+ik with n and k as real and imaginary parts respectively, is determined from the reflection spectrum and fitting to Cauchy equations. Reflection from a thin film Article is given by

$$R ( λ ) = \frac{{{R}_{1} ( λ )}^{2} {e}^{α {d}_{l}} + {{R}_{2} ( λ )}^{2} {e}^{- α {d}_{l}} + 2 {R}_{1} ( λ ) {R}_{2} ( λ ) cos ( {ϕ}_{l} )}{{e}^{α {d}_{l}} + {{R}_{1} ( λ )}^{2} {{R}_{2} ( λ )}^{2} {e}^{- α {d}_{l}} + 2 {R}_{1} ( λ ) {R}_{2} ( λ ) cos ( {ϕ}_{l} )}$$

wherein R is the measured reflection, R₁=|(nₐ*−nₗ*)/(nₐ*+nₗ*)|² and R₂=|(nₗ*−nₛ*)/(nₗ*+nₛ*)|² is the normal incident reflection from the air-Article interface and from the Article-substrate interface, respectively, and the subscripts a=air, l=Article layer, and s=substrate. In typical examples this substrate is silicon. λ is the wavelength of light measured, a is the absorption coefficient of the film and given by α(λ)=4πk(λ)/λ, d is the film thickness, and φ is the angle of incidence. The fitted Cauchy equations are

$$n ( λ ) = {A}_{n} + {B}_{n} / {λ}^{2}$$

$$and$$

$$k ( λ ) = {A}_{k} {e}^{{B}_{k} [ 1.24 ( \frac{1}{λ} - \frac{1}{0.2} ) ]}$$

wherein An, Bn, Ak and Bk are fitted coefficients using measurements across the solar spectrum. For several example articles of varying composition and index of refraction the index and fitted parameters are shown in the table below.

| n (ave) | An (ave) | Bn (ave) | Ak (ave) | Bk (ave) | MSE (%) |
|---|---|---|---|---|---|
| 2.3667 | 2.2803 | 0.034107 | 0.25956 | 0.9298 | 2.014 |
| 2.3097 | 2.2192 | 0.032616 | 0.19123 | 1.5495 | 2.704 |
| 2.24 | 2.1088 | 0.049801 | 0.12135 | 2.3719 | 2.85 |
| 1.8673 | 1.6003 | 0.1135 | 0.02373 | 4.7347 | 2.318 |
| 1.7451 | 1.6179 | 0.051855 | 0.00985 | 4.83 | 1.944 |
| 1.6883 | 1.6066 | 0.03274 | 0.006921 | 4.8258 | 1.96 |
| 1.6431 | 1.6118 | 0.011134 | 0.003104 | 3.146 | 2.112 |
| 1.6145 | 1.6184 | −0.00377 | 0.011489 | 1.29 | 2.208 |
| 1.5476 | 1.5349 | 0.005062 | 0.004812 | 1.2716 | 3.1 |
| 1.4943 | 1.4869 | 0.002957 | 0 | 0 | 1.504 |

The Articles are analyzed to determine overall composition as a function of oxygen flow rate using a Fourier-Transform infrared (IR) spectrometer (as set forth in FIG. 7). More specifically, the FT-IR spectrometer is used to determine how the gradient of the GRIC changes from hydrogenated silicon carbide (SiC:H) to hydrogenated silicon oxycarbide (SiOC:H) over time as a function of the oxygen flow rate. The infrared spectrometer is commercially available from Thermo Scientific under the trade name of Nexus.

As set forth in FIG. 6, the ellipsometric data suggests that increased flow rate of oxygen results in increased deposition rate and decreased refractive indices. Without intending to be bound by any particular theory, it is believed that these results are based on a gradual transition from hydrogenated silicon carbide (SiC:H) to hydrogenated silicon oxycarbide (SiOC:H) expressed by significant changes in Si—C and Si—O stretching oscillations as seen in the infrared spectrum of FIG. 7.

### Evaluation of Percentage Light Transmittance as a Function of Wavelength:

An additional series of Articles are also formed using the General Procedure described above and are evaluated to determine percentage light transmittance as a function of wavelength. After formation, these Articles are evaluated using a Cary 500 UV-Vis-NIR spectrophotometer that is commercially available from Varian.

As set forth in FIG. 8, the data suggest that the light transmission spectrum of the GRIC is very similar to that of an uncoated reference glass substrate indicating low absorbance. This data demonstrates that the GRIC of the instant invention absorbs a minimum amount of light which is advantageous when forming a variety of electronic articles.

### Second Series of Examples—General Procedure

In a second series of Examples, glass slides and monocrystalline silicon wafers as substrates of the Articles are used. The substrates are inserted into a parallel-plate capacitive plasma reactor operating in dual-frequency (DF) configuration, to first receive an inorganic layer including hydrogenated silicon carbide (SiC:H) disposed thereon and then receive an GRIC also disposed thereon. The GRIC is disposed using the same conditions as those described above while the inorganic layer is disposed using conditions different from those above. The conditions for disposing the inorganic layer are described immediately below.

In these examples, the substrates are heated to approximately 300° C. but the walls of the reactor remain unheated. To dispose the inorganic layer, the reactor is operated in a reactive ion-etching (RIE) mode wherein a bottom electrode is operated at a power of 420 W and a pressure of the chamber is about 450 mTorr. Trimethylsilane, which is a non-pyrophoric organosilicon gas, is utilized as a hydrogenated silicon carbide (SiC:H) precursor gas at an Ar:(CH₃)₃SiH ratio of about 8. These conditions provide a deposition rate of hydrogenated silicon carbide (SiC:H) of about 60 nm/min on the substrates. A thickness of the inorganic layer is selected to minimize light absorption and ranges from about 25 to about 75 nm.

After the inorganic layer is disposed on the glass slides, a reactive gas mixture of trimethylsilane ((CH₃)₃SiH) and argon (Ar) is introduced into the dual frequency reactor and the PECVD process is initiated. The PECVD process forms the GRIC on the inorganic layer using the same procedure and parameters as described in the General Procedure for the first series of examples. Subsequently, a dielectric layer is disposed on the GRIC. The dielectric layer is formed by immersing the glass slides in a solution of poly(dimethylsiloxane) (PDMS) and then allowing the PDMS to cure.

### Evaluation of Reflection as a Function of Wavelength:

Still another series of Articles are also formed using the General Procedure described above and are evaluated to determine reflection as a function of wavelength. After formation, these Articles are evaluated using a spectrometer commercially available from M.U.T. Group under the trade name of Tristan.

In FIG. 9, the reduced reflectance achieved by a trilayer antireflective structure (GRIC+inorganic layer+dielectric layer) of various embodiments the Articles of this invention is compared to reflection of uncoated silicon (e.g. optoelectronic semiconductor), reflection of the GRIC itself, and the bilayer antireflective structure (GRIC+inorganic layer), for normal incident light. It is evident from FIG. 9 that there is a significant reduction that is achieved using the trilayer structure.

The invention has been described in an illustrative manner, and it is to be understood that the terminology which has been used is intended to be in the nature of words of description rather than of limitation. Many modifications and variations of the present invention are possible in light of the above teachings, and the invention may be practiced otherwise than as specifically described.

It is to be understood that the appended claims are not limited to express and particular compounds, compositions, or methods described in the detailed description, which may vary between particular embodiments which fall within the scope of the appended claims. With respect to any Markush groups relied upon herein for describing particular features or aspects of various embodiments, it is to be appreciated that different, special, and/or unexpected results may be obtained from each member of the respective Markush group independent from all other Markush members. Each member of a Markush group may be relied upon individually and or in combination and provides adequate support for specific embodiments within the scope of the appended claims.

It is also to be understood that any ranges and subranges relied upon in describing various embodiments of the present invention independently and collectively fall within the scope of the appended claims, and are understood to describe and contemplate all ranges including whole and/or fractional values therein, even if such values are not expressly written herein. One of skill in the art readily recognizes that the enumerated ranges and subranges sufficiently describe and enable various embodiments of the present invention, and such ranges and subranges may be further delineated into relevant halves, thirds, quarters, fifths, and so on. As just one example, a range “of from 0.1 to 0.9” may be further delineated into a lower third, i.e., from 0.1 to 0.3, a middle third, i.e., from 0.4 to 0.6, and an upper third, i.e., from 0.7 to 0.9, which individually and collectively are within the scope of the appended claims, and may be relied upon individually and/or collectively and provide adequate support for specific embodiments within the scope of the appended claims. In addition, with respect to the language which defines or modifies a range, such as “at least,” “greater than,” “less than,” “no more than,” and the like, it is to be understood that such language includes subranges and/or an upper or lower limit. As another example, a range of “at least 10” inherently includes a subrange of from at least 10 to 35, a subrange of from at least 10 to 25, a subrange of from 25 to 35, and so on, and each subrange may be relied upon individually and/or collectively and provides adequate support for specific embodiments within the scope of the appended claims. Finally, an individual number within a disclosed range may be relied upon and provides adequate support for specific embodiments within the scope of the appended claims. For example, a range “of from 1 to 9” includes various individual integers, such as 3, as well as individual numbers including a decimal point (or fraction), such as 4.1, which may be relied upon and provide adequate support for specific embodiments within the scope of the appended claims.

1. A method of forming an electronic article comprising:
an optoelectronic semiconductor having a refractive index of 3.7±2;
a dielectric layer that is disposed on the optoelectronic semiconductor and that has a thickness of at least 50 μm and a refractive index of 1.4±0.1; and
a gradient refractive index coating that is disposed on the optoelectronic semiconductor and sandwiched between the optoelectronic semiconductor and the dielectric layer, that has a thickness of from 50 to 400 nm, that has a refractive index varying along the thickness from 2.7±0.7 at a first end to 1.5±0.1 at a second end adjacent to the dielectric layer, and that comprises a gradient of a carbide and an oxycarbide along the thickness, wherein each of the carbide and the oxycarbide independently comprises at least one of a silicon atom and a germanium atom,
said method comprising the steps of;
A. continuously depositing the gradient refractive index coating on the optoelectronic semiconductor using plasma-enhanced chemical vapor deposition in a dual frequency configuration, and subsequently
B. disposing the dielectric layer on the gradient refractive index coating to form the electronic article.

2. A method as set forth in claim 1 wherein the carbide is further defined as hydrogenated silicon carbide (SiC:H) and the oxycarbide is further defined as hydrogenated silicon oxycarbide (SiOC:H).

3. A method as set forth in claim 1 wherein the carbide is further defined as hydrogenated germanium carbide (GeC:H) and the oxycarbide is further defined as hydrogenated germanium oxycarbide (GeOC:H).

4. A method as set forth in claim 1 wherein the carbide is further defined as hydrogenated silicon germanium carbide (SiGeC:H) and the oxycarbide is further defined as hydrogenated silicon germanium oxy-carbide (SiGeOC:H).

5. A method as set forth in claim 1 wherein the electronic article has a light reflection of less than 5% over a range of wavelengths from 400 to 1200 nm as determined using UV/Vis Spectrometry.

6. A method as set forth in claim 1 wherein the step of continuously depositing in the dual frequency configuration occurs at a first frequency of from 70 kHz to 400 kHz and at a second frequency of from 13.5 MHz to 13.6 MHz simultaneously.

7. A method as set forth in claim 1 wherein the step of continuously depositing occurs at a pressure of from 40 mTorr to 350 mTorr.

8. A method as set forth in claim 1 wherein the step of continuously depositing comprises the step of injecting oxygen into the plasma.

9. A method as set forth in claim 1 further comprising the step of disposing an inorganic layer directly on the optoelectronic semiconductor sandwiched between the optoelectronic semiconductor and the gradient refractive index coating wherein the inorganic layer has a refractive index of from 2.4 to 2.7±0.7.

10. A method as set forth in claim 1 wherein the electronic article is further defined as a photovoltaic cell module.

11. A method as set forth in claim 1 wherein the electronic article is further defined as a light emitting diode.

12. An electronic article formed from the method set forth in claim 1.

13. An electronic article comprising:
A. an optoelectronic semiconductor having a refractive index of 3.7±2;
B. a dielectric layer that is disposed on said optoelectronic semiconductor and that has a thickness of at least 50 μm and a refractive index of 1.4±0.1; and
C. a gradient refractive index coating that is disposed on said optoelectronic semiconductor and sandwiched between said optoelectronic semiconductor and said dielectric layer, that has a thickness of from 50 to 400 nm, that has a refractive index varying along the thickness from 2.7±0.7 at a first end to 1.5±0.1 at a second end adjacent to the dielectric layer, and that comprises a gradient of a carbide and an oxycarbide along said thickness, wherein each of said carbide and said oxycarbide independently comprises at least one of a silicon atom and a germanium atom.

14. An electronic article as set forth in claim 13 wherein said carbide is further defined as hydrogenated silicon carbide (SiC:H) and said oxycarbide is further defined as hydrogenated silicon oxycarbide (SiOC:H).

15. An electronic article as set forth in claim 13 wherein said carbide is further defined as hydrogenated germanium carbide (GeC:H) and said oxycarbide is further defined as hydrogenated germanium oxycarbide (GeOC:H).

16. An electronic article as set forth in claim 13 wherein said carbide is further defined as hydrogenated silicon germanium carbide (SiGeC:H) and said oxycarbide is further defined as hydrogenated silicon germanium oxy-carbide (SiGeOC:H).

17. An electronic article as set forth in claim 13 having a light reflection of less than 5% over a range of wavelengths from 400 to 1200 nm as determined using UV/Vis Spectrometry.

18. An electronic article as set forth in claim 13 further comprising an inorganic layer disposed directly on said optoelectronic semiconductor sandwiched between said optoelectronic semiconductor and said gradient refractive index coating wherein said inorganic layer has a refractive index of from 2.4 to 2.7±0.7.

19-20. (canceled)

21. An electronic article as set forth in claim 13 that is further defined as a photovoltaic cell module.

22. An electronic article as set forth in claim 13 that is further defined as a light emitting diode.

23-25. (canceled)
